(19) United States
(12) Patent Application Publication
(10) Pub. No.: US 2023/0323524 A1
(43) Pub. Date: Oct. 12, 2023

(54) QUARTZ CRYSTAL SENSOR COATED WITH GOLD-ALUMINUM BY MAGNETRON SPUTTERING

(71) Applicant: Cantech Inc., Fort Worth, TX (US)

(72) Inventor: Gonghe Xiao, Fort Worth, TX (US)

(21) Appl. No.: 17/715,713

(22) Filed: Apr. 7, 2022

(51) Int. Cl. C23C 14/18; C23C 14/58; C23C 14/35

(52) U.S. Cl. CPC C23C 14/185; C23C 14/35; C23C 14/5806

(57) ABSTRACT

A method of constructing a sensor, including providing a quartz crystal having a first side and a second side, magnetron sputtering of 4000 to 13000 angstroms of aluminum directly on the quartz crystal first side and the quartz crystal second side, heating the aluminum sputtered quartz crystal to 100° C. to 500° C., magnetron sputtering of gold directly onto the aluminum sputtered quartz crystal first side and the aluminum sputtered quartz crystal second side, wherein the thickness of the aluminum is between 3 times and 40 times greater than the thickness of the gold and wherein the magnetron sputtering of aluminum, the heating and the magnetron sputtering of the gold is performed in a vacuum.

### TECHNICAL FIELD OF THE APPLICATION

This application relates to a quartz crystal coating and more specifically to a magnetron sputtered quartz crystal coating.

### BACKGROUND OF THE APPLICATION

Conventionally, in a quartz sensor the quartz crystal is coated with metal conductive film, as a sensor widely used in the thermal evaporation coating machine, the amount of coating material causes the change of its resonance frequency on the crystal quartz, so the frequency change can indirectly correspond the film thickness or coating rate. Conventional quartz crystal coatings are comprised of gold, silver, and silver aluminum.

### SUMMARY OF THE APPLICATION

Example embodiments of the present application provide at least a first example method of the present application includes at least one of providing a quartz crystal having a first side and a second side, magnetron sputtering of 4000 to 13000 angstroms of aluminum directly on the quartz crystal first side and the quartz crystal second side, heating the aluminum sputtered quartz crystal to 100° C. to 500° C., magnetron sputtering of gold directly onto the aluminum sputtered quartz crystal first side and the aluminum sputtered quartz crystal second side, wherein the thickness of the aluminum is between 3 times and 40 times greater than the thickness of the gold and wherein the magnetron sputtering of aluminum, the heating and the magnetron sputtering of the gold is performed in a vacuum.

A further example embodiment of the present application provides a quartz crystal sensor, including a quartz crystal having a first side and a second side, 4000 to 13000 angstroms of magnetron sputtered aluminum directly on the quartz crystal first side and the quartz crystal second side, wherein the magnetron sputtered aluminum is annealed and magnetron sputtered gold directly onto the aluminum sputtered quartz crystal first side and the aluminum sputtered quartz crystal second side, wherein the aluminum is between 3 times and 40 times greater than the thickness of the gold.

### BRIEF DESCRIPTION OF THE DRAWINGS

FIG. 1 illustrates an example cross section of the gold-aluminum coated quartz crystal sensor according to example embodiments.

FIG. 2 illustrates an example front view of the gold-aluminum coated quartz crystal sensor according to example embodiments.

FIG. 3 illustrates an example method according to example embodiments.

### DETAILED DESCRIPTION OF THE APPLICATION

It will be readily understood that the components of the present application, as generally described and illustrated in the figures herein, may be arranged and designed in a wide variety of different configurations. Thus, the following detailed description of the embodiments of a method, apparatus, and system, as represented in the attached figures, is not intended to limit the scope of the application as claimed but is merely representative of selected embodiments of the application.

The features, structures, or characteristics of the application described throughout this specification may be combined in any suitable manner in one or more embodiments. For example, the usage of the phrases “example embodiments”, “some embodiments”, or other similar language, throughout this specification refers to the fact that a particular feature, structure, or characteristic described in connection with the embodiment may be included in at least one embodiment of the present application. Thus, appearances of the phrases “example embodiments”, “in some embodiments”, “in other embodiments”, or other similar language, throughout this specification do not necessarily all refer to the same group of embodiments, and the described features, structures, or characteristics may be combined in any suitable manner in one or more embodiments.

A quartz crystal is a piezoelectric material that may be made to oscillate by applying a voltage across the surface of the quartz crystal. The principle of operation of the sensor is based on the fact that the mass of a deposited film on a quartz crystal may be measured by monitoring a change in crystal's oscillating frequency. By tracking the frequency response of the quartz crystal during the coating process a determination may be made of the film growth and deposition rate onto the electrode surface.

Magnetron sputtering is a deposition based on impacts between incident particles and targets. Sputtering is performed at a low pressure where incident particles impact a target atom and transmits part of the momentum to the target atom. During this process some target atoms on the surface gain sufficient momentum for outward motion and are sputtered out of the target and onto the quartz crystal. Magnetron sputtering increases the plasma density focusing a magnetic field on the surface of a target cathode and utilizing the focusing of the magnetic field on the charged particles to increase the sputtering rate.

An alloy quartz crystal with gold-aluminum depositions and a process for depositing the aluminum and gold by magnetron sputtering is disclosed. Compared with a traditional gold, silver and silver-aluminum quartz crystal, the gold-aluminum alloy quartz crystal has increased adhesion, higher heat dissipation, higher conductivity, hardness, and a lower impedance. A quartz crystal that has deposited aluminum and gold may be used to measure a film thickness and deposition rate in a thermal evaporation coating machine.

The quartz crystal is coated with a metal conductive film, as a metal coated quartz sensor may be used in a thermal evaporation coating machine. The deposited thickness of coating material causes a frequency change of the crystal quartz. The frequency change is related to a deposited film thickness or a film coating rate on the quartz sensor.

The materials used as metal conductive films are mainly gold, silver, and aluminum. Among gold, silver and aluminum, the quartz crystal with aluminum as conductive layer is too soft and easily scratched and oxidized. The impedance, conductivity and thermal conductivity of gold are better than aluminum.

The use of a gold-aluminum alloy coating on quartz not only ensures a stress resistance effect of the quartz crystal but it also overcomes the shortcomings of large impedance and low conductivity and thermal conductivity in an aluminum coated quartz crystal. A gold-aluminum alloy is an intermetallic compound of gold and aluminum that occurs between the two metals.

If a traditional thermal evaporation process is used to deposit an alloy metal film on quartz crystal, the different metals are evaporated, and the proportion of evaporated metal components deposited may be different from the source proportion due to different melting temperatures of source metals. Since the melting points of different metals are different, they may fail to reach the expected proportion of the deposited alloy components, thus affecting the performance of quartz crystal sensor. The solution provided by the disclosure selects the magnetron sputtering coating process, to control the coating amount of gold and aluminum respectively, yielding an expected composition ratio of gold and aluminum in the alloy film.

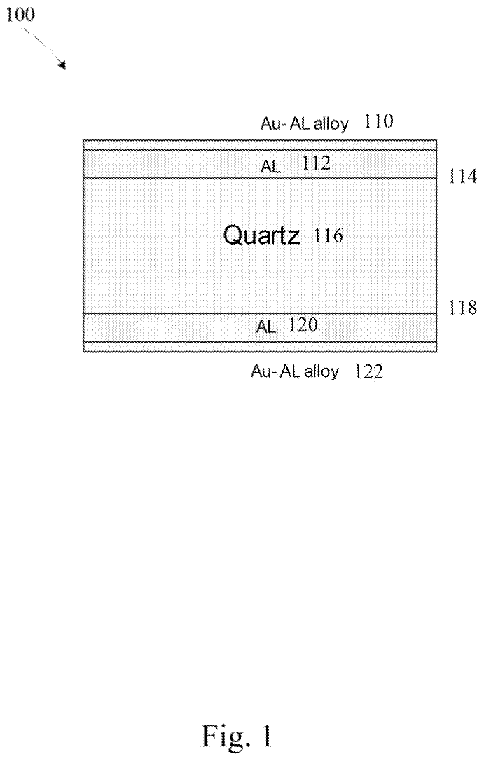

FIG. 1 illustrates an example cross section of the gold-aluminum coated quartz crystal sensor. The quartz crystal 116 has a first side 114 and a second side 116. On the quartz crystal a top portion aluminum sputtered section 112 is deposited and a bottom portion aluminum sputtered section 120 is sputtered on the first side 114 and the second side 116 respectively. The aluminum sputtered portion is 4000 to 13000 angstroms thick. A gold top portion 110 is sputtered on the top portion aluminum sputtered section 112 and a gold bottom portion 122 is sputtered on the bottom portion aluminum sputtered section 120. The quartz crystal with the aluminum sputtered sections 112 and 120 is annealed to 100° C. to 500° C.. The thickness of the aluminum is between 3 times and 40 times greater than the thickness of the gold. The heating and the magnetron sputtering of the gold is performed in a vacuum.

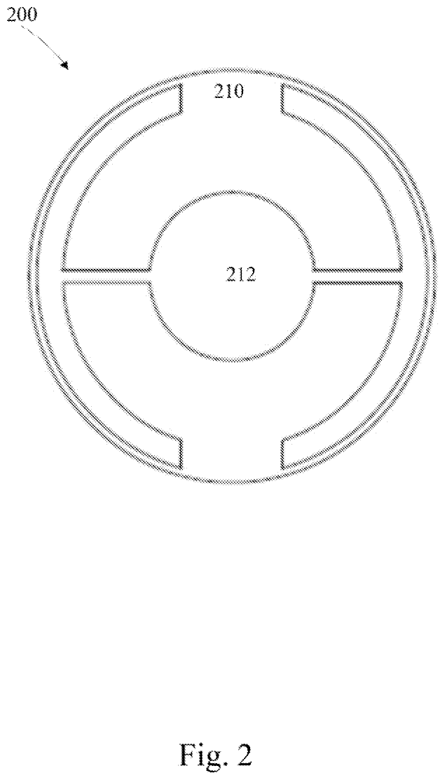

FIG. 2 illustrates an example front view of the gold-aluminum coated quartz crystal sensor. The crystal quartz 210 has a magnetron sputtered coating 212.

An example coating process to coat the quartz crystal with a gold-aluminum alloy are as follows:

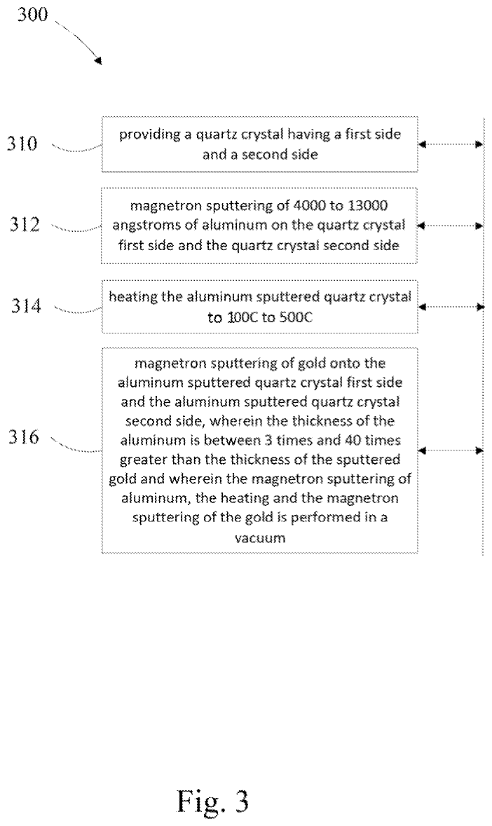

In one example, a multi-chamber magnetron sputtering equipment has two aluminum targets and two gold targets in their coating chambers. Double targets may be used for double-sided magnetron sputtering of a crystal quartz sensor, FIG. 3 310, to be coated on the sample holder in its coating machine. The sample holder may move between the double targets.

The magnetron sputtering may simultaneously coat aluminum on two sides of the quartz crystal, FIG. 3 312. The thickness of one side of the aluminum layer is D, which is between 4000-13000 Å(Angstrom).

The aluminized quartz crystal may be moved into a heating chamber to heat the aluminized substrate to 100-500° C., FIG. 3 314.

The quartz crystal may be conveyed into the gold coating chamber, and the gold may be plated on both sides of the aluminized quartz crystal FIG. 3, 316. The conveyance of the plated quartz crystal may be carried out in vacuum. Keeping the aluminum coated quartz crystal allows the sensor to kept at high temperature during gold plating of the aluminized quartz. Gold atoms are deposited on the aluminum film and may be fused with the aluminum film to form a uniform and mutually permeable gold-aluminum alloy film. The thickness of one side of the aluminum layer is D and the thickness of one side of the gold film is H. The thickness of the gold coating is targeted to make the proportion of gold-aluminum alloy coating X=D/H is between 3-40.

If the X value is too high, and the proportion of gold is too low, the heat dissipation and conductivity and hardness are reduced, and the impedance is increased. If the coating is too rich in aluminum, it is easily scratched or indented. If the X value is too low, and the proportion of gold is too high, which increases the cost and will be unevenly distributed on the aluminum forming gold and affecting the appearance and the stress resistance of the sensor product.

Compared with the traditional gold, silver and silver-aluminum quartz crystal, the gold-aluminum alloy quartz crystal has increased heat dissipation, increased conductivity, increased hardness, and lowered impedance. When the quartz crystal is used to sense coating thickness and coating rate, it has a stable, wide response frequency range.

FIG. 3 illustrates an example method including providing 310 a quartz crystal having a first side and a second side, magnetron sputtering 312 of 4000 to 13000 angstroms of aluminum on the quartz crystal first side and the quartz crystal second side, heating 314 the aluminum sputtered quartz crystal to 100° C. to 500° C., magnetron sputtering 316 of gold onto the aluminum sputtered quartz crystal first side and the aluminum sputtered quartz crystal second side, wherein the thickness of the aluminum is between 3 times and 40 times greater than the thickness of the gold and wherein the magnetron sputtering of aluminum, the heating and the magnetron sputtering of the gold is performed in a vacuum. In one embodiment, the vacuum is not broken between the steps of the method.

Another example method consists of providing a quartz crystal having a first side and a second side, magnetron sputtering of 4000 to 13000 angstroms of aluminum on the quartz crystal first side and the quartz crystal second side, heating the aluminum sputtered quartz crystal to 100° C. to 500° C., magnetron sputtering of gold onto the aluminum sputtered quartz crystal first side and the aluminum sputtered quartz crystal second side, wherein the thickness of the aluminum is between 3 times and 40 times greater than the thickness of the gold and wherein the magnetron sputtering of aluminum, the heating and the magnetron sputtering of the gold is performed in a vacuum. In one embodiment, the vacuum is not broken between the steps of the method.

The interface of the aluminum and the gold may contain impurity components. The impurity components may come from the targets, environmental material and from air after the quartz crystal is taken out from the vacuum chamber. For example, the impurity of an aluminum target may include micro elements such as Fe, Cu, Si, Ag and others. When the quartz crystal is exposed to air, oxygen or other components from air may be absorbed on the sample. The impurity should be kept as low as possible.

Although an exemplary embodiment of the system and method of the present application has been illustrated in the accompanied drawings and described in the foregoing detailed description, it will be understood that the application is not limited to the embodiments disclosed, but is capable of numerous rearrangements, modifications, and substitutions without departing from the spirit or scope of the application as set forth and defined by the following claims. Further, the functionality described herein may be performed at various times and in relation to various events, internal or external to the modules or components.

Presenting the above-described functions as being performed by a “system” is not intended to limit the scope of the present application in any way but is intended to provide one example of many embodiments of the present application. Indeed, methods, systems and apparatuses disclosed herein may be implemented in localized and distributed forms.

It will be readily understood that the components of the application, as generally described and illustrated in the figures herein, may be arranged and designed in a wide variety of different configurations. Thus, the detailed description of the embodiments is not intended to limit the scope of the application as claimed but is merely representative of selected embodiments of the application.

One having ordinary skill in the art will readily understand that the application as discussed above may be practiced with steps in a different order, and/or with hardware elements in configurations that are different than those which are disclosed. Therefore, although the application has been described based upon these preferred embodiments, it would be apparent to those of skill in the art that certain modifications, variations, and alternative constructions would be apparent, while remaining within the spirit and scope of the application. To determine the metes and bounds of the application, therefore, reference should be made to the appended claims.

While preferred embodiments of the present application have been described, it is to be understood that the embodiments described are illustrative only and the scope of the application is to be defined solely by the appended claims when considered with a full range of equivalents and modifications thereto.

What is claimed is:

1. A method of constructing a sensor, comprising:
providing a quartz crystal having a first side and a second side,
magnetron sputtering of 4000 to 13000 angstroms of aluminum directly on the quartz crystal first side and the quartz crystal second side;
heating the aluminum sputtered quartz crystal to 100° C. to 500° C.;
magnetron sputtering of gold directly onto the aluminum sputtered quartz crystal first side and the aluminum sputtered quartz crystal second side, wherein the thickness of the aluminum is between 3 times and 40 times greater than the thickness of the gold; and
wherein the magnetron sputtering of aluminum, the heating and the magnetron sputtering of the gold is performed in a vacuum.

2. The method of constructing a sensor of claim 1 further comprising maintaining an unbroken high vacuum during the sputtering of the aluminum, the heating and sputtering of the gold.

3. A quartz crystal sensor, comprising:
a quartz crystal having a first side and a second side;
4000 to 13000 angstroms of magnetron sputtered aluminum directly on the quartz crystal first side and the quartz crystal second side, wherein the magnetron sputtered aluminum is annealed; and
magnetron sputtered gold directly onto the aluminum sputtered quartz crystal first side and the aluminum sputtered quartz crystal second side, wherein the aluminum is between 3 times and 40 times greater than the thickness of the gold.

4. The quartz crystal sensor of claim 3 wherein an interface of the aluminum and the gold further is comprising of one or more impurity components out of Fe, Cu, Si, Ag, and oxygen.
